(19) United States
(12) Patent Application Publication
(10) Pub. No.: US 2016/0368020 A1
(43) Pub. Date: Dec. 22, 2016

(54) METHOD FOR MANUFACTURING FILM FOR OPTOELECTRONIC ELEMENT

(71) Applicant: Corning Precision Materials Co., Ltd., Chungcheongnam-do (KR)

(72) Inventors: Hong Yoon, Chungcheongnam-do (KR); Joo Young Lee, Chungcheongnam-do (KR)

(73) Assignee: Corning Precision Materials Co., Ltd., Chungcheongnam-do (KR)

(21) Appl. No.: 15/103,074

(22) PCT Filed: Dec. 8, 2014
(86) PCT No.: PCT/KR2014/011995

§ 371 Date: Jun. 9, 2016

(30) Foreign Application Priority Data
Dec. 9, 2013 (KR) 10-2013-0152429

(51) Int. Cl. B05D 3/04; B05D 1/02; B05D 1/00; H01L 51/00

(52) U.S. Cl. CPC B05D 3/0493; H01L 51/0097; B05D 3/0406; B05D 1/02; B05D 1/005; H01L 51/0021; H01L 2251/5338; H01L 51/5275

(57) ABSTRACT

The present invention relates to a method for manufacturing a film for an optoelectronic element and, more specifically, to a method for manufacturing a film for an optoelectronic element, which can improve the optical characteristics of an optoelectronic element and can be applied to even flexible optoelectronic elements. To this end, the present invention provides the method for manufacturing a film for an optoelectronic element, comprising: a bubble generation step for generating a large quantity of bubbles inside a polymer resin by stirring the polymer resin; a bubble density control step for controlling the density of the bubbles inside the polymer resin by exposing, to vacuum, the polymer resin in which bubbles are generated; and a coating film formation step for forming a coating film having a plurality of pores dispersed therein by coating and drying the polymer resin on a substrate.

### TECHNICAL FIELD

The present disclosure relates to a method of manufacturing a film for optoelectronics. The present disclosure also relates to a method of manufacturing a film for optoelectronics that can improve the optical characteristics of optoelectronics and be used in flexible optoelectronics.

### BACKGROUND ART

Next-generation technologies and products that have recently come to prominence provide optoelectronics based on organic materials. For example, typical optoelectronics may include organic light-emitting diodes (OLEDs) used in mobile displays and solid state lighting (SSL) and organic solar cells having organic materials used for light-absorbing layers. In such optoelectronics, organic materials having significant performance levels have been developed as the result of intensive research into organic materials.

Such optoelectronics include organic-inorganic composite layers in which an organic material and an inorganic material are combined. Here, typical inorganic materials used in optoelectronics are transparent electrodes, metal reflective electrodes, glass substrates, and so on. However, in the case of inorganic materials, significant amounts of light may be lost due to differences in refractive indices or the like, whereby improvements in light efficiency are significantly restricted.

To overcome this limitation, conventionally, textured nanopatterns are formed in the front surfaces of optoelectronic devices. However, when a nanopattern is formed on an organic-inorganic composite layer, the textured nanopattern makes it impossible to ensure that thin films of the organic-inorganic composite layer are planar. This means that the nanopattern formed on the organic-inorganic composite layer increases the possibility of sharp portions being formed on the organic-inorganic composite layer. For example, in an organic light-emitting diode (OLED) having a multilayer structure of very thin organic and inorganic films, when an anode bonded to the nanopattern has sharp protrusions transferred from the nanopattern, current may be concentrated on the sharp protrusions. This consequently causes a significant amount of leakage current or lowers the efficiency of electricity.

Thus, a planarization film is necessarily added to prevent such a degradation in electrical characteristics.

However, it is a very difficult process to perfectly planarize a textured nanopattern using a thin planarization film having a thickness of several hundred nanometers. Specifically, when a planarization film is conventionally deposited on the nanopattern, the depressions in the nanopattern are filled with a material of the planarization film, so that the planarization film is formed to conform to the shape of the nanopattern. Thus, the flatness of the planarization film must be significantly low.

Recently, flexibility is the main trend in the area of optoelectronics. Thus, functional films available for such physical requirements are in demand.

### Prior Art Document

Japanese Unexamined Patent Application No. 2011-214046 (Oct. 27, 2011)

### DISCLOSURE

### Technical Problem

Accordingly, the present invention has been made in consideration of the above problems occurring in the related art, and the present invention is provided to propose a method of manufacturing a film for optoelectronics that can improve optical characteristics of optoelectronics and can be used in flexible optoelectronics.

### Technical Solution

According to an aspect of the present disclosure, provided is a method of manufacturing a film. The method may include: forming a plurality of bubbles within a polymer resin by stirring the polymer resin; controlling a density of the bubbles within the polymer resin by exposing the polymer resin containing the bubbles to a vacuum; and forming a coating film having a plurality of voids dispersed therein by coating a substrate with the polymer resin and then drying the polymer resin, to obtain a film for an optoelectronic device.

Here, stirring the polymer resin may be performed for 10 minutes or longer.

The viscosity of the polymer resin may range from 100 cP to 100,000 cP.

The polymer resin may be an ultraviolet (UV) curable resin.

Controlling the density of the bubbles may include inserting a bath containing the polymer resin into a desiccator, and creating the vacuum in the desiccator by operating a vacuum pump connected to the desiccator.

Here, the period of time for which the vacuum pump is operated may be inversely proportional to the density of the bubbles.

Coating the substrate may be performed using one coating method selected from the group consisting of spin coating, bar coating, and spray coating.

The substrate may be a flexible substrate.

### Advantageous Effects

According to the present disclosure, it is possible to form bubbles within a polymer resin and control the density of the formed bubbles through a series of processing steps of stirring the polymer resin having a high level of viscosity and then exposing the polymer resin to a vacuum. When the resultant polymer resin is used as a functional film for optoelectronics, optical characteristics of optoelectronics can be improved. In addition, the polymer resin may be used as an internal light extraction layer of a flexible OLED.

### DESCRIPTION OF DRAWINGS

FIG. 1 is a process flowchart illustrating a method of manufacturing a film for optoelectronics according to an exemplary embodiment; and

FIG. 2 is a conceptual cross-sectional view schematically illustrating a film for optoelectronics according to an exemplary embodiment and an optoelectronic device including the same.

### MODE FOR INVENTION

Hereinafter, reference will be made to a method of manufacturing a film for optoelectronics according to an exemplary embodiment in conjunction with the accompanying drawings.

In the following description, detailed descriptions of known functions and components incorporated herein will be omitted in the case that the subject matter of the present disclosure is rendered unclear by the inclusion thereof.

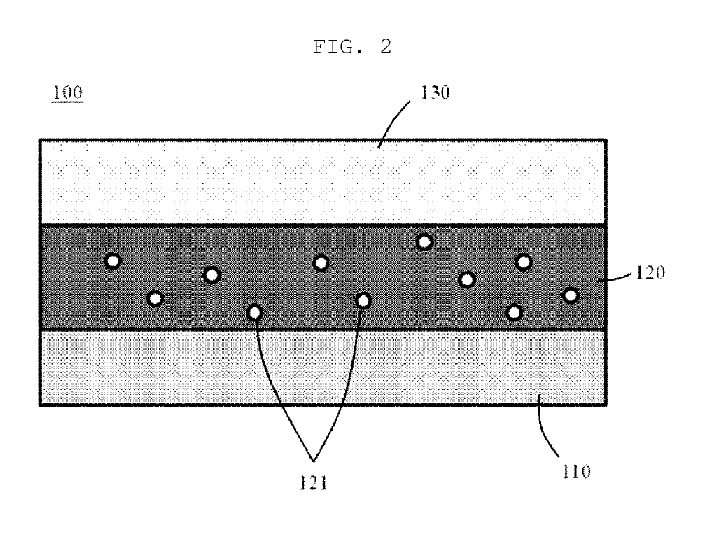

A method of manufacturing a film for optoelectronics according to an exemplary embodiment is a method of manufacturing a film functioning to improve optical characteristics of an optoelectronic device (100 in FIG. 2), for example, an organic light-emitting diode (OLED) or a photovoltaic cell.

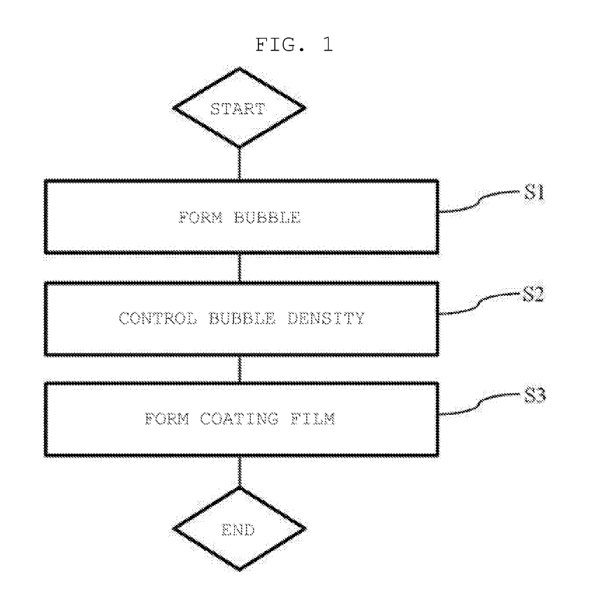

As illustrated in FIG. 1, the method of manufacturing a film for optoelectronics according to the present embodiment includes a bubble-forming step S1, a bubble density-controlling step S2, and a coating film-forming step S3.

First, the bubble-forming step S1 is a step of forming a large number of bubbles within a material of a coating film (120 in FIG. 2) of a film for optoelectronics that will be manufactured by subsequent processing. The film for optoelectronics manufactured according to the present embodiment may be used as, for example, a film for flexible OLEDs. In this regard, in the bubble-forming step S1, a polymer resin may be selected and used as the material of the coating film (120 in FIG. 2).

In the bubble-forming step S1, to form a large number of bubbles within the polymer resin, the liquid polymer resin is poured into a bath and is then stirred. The number of bubbles to be formed can be controlled by the time and speed of the stirring. That is, the number of bubbles to be formed within the polymer resin increases with increases in the time and speed of the stirring. It is preferable that the polymer resin be stirred for 10 minutes or longer, since the bubble-forming step S1 according to the present embodiment is intended for the formation of a large number of bubbles. Here, the faster the speed of the stirring is, the more the formation of bubbles is facilitated. Thus, according to the present embodiment, the speed of the stirring is not limited to a specific value.

As the material is more viscous, more bubbles are easily formed within the material by the stirring, i.e. bubbles are formed with a higher density. Thus, according to the present embodiment, a higher-viscosity material from among polymer resins may be selected as the material of the coating film (120 in FIG. 2). For example, a material having a viscosity ranging from 100 cP to 100,000 cP may be selected. In the bubble-forming step S1, for example, an ultraviolet (UV) curable resin having a viscosity ranging from 100 cP to 100,000 cP may be selected as the material of the coating film (120 in FIG. 2). The refractive index of the UV curable resin may be adjusted through adjusting manufacturing and curing conditions. When the film for optoelectronics manufactured according to the present embodiment is used for an internal light extraction layer of an OLED, the refractive index thereof may be adjusted in the range from 1.3 to 1.7.

Then, the bubble density-controlling step S2 is a step of controlling the density of the large number of bubbles formed within the polymer resin in the bubble-forming step S1. In this regard, in the bubble density-controlling step S2, the polymer resin having the large number of bubbles formed therein is exposed to the air. Specifically, in the bubble density-controlling step S2, the bath containing the polymer resin is inserted into a desiccator, and then a vacuum is created in the desiccator by operating a vacuum pump connected to the desiccator. Here, the operating period of the vacuum pump, i.e. the period in which the polymer resin is exposed to the vacuum, is inversely proportional to the density of the bubbles. That is, the longer the period for which the polymer resin is exposed to the vacuum, the smaller the number of bubbles formed within the polymer resin is. When the polymer resin is continuously exposed to the vacuum for a prolonged period of time, all of the bubbles formed within the polymer resin disappear at a specific point in time.

According to the present embodiment, the bubbles formed within the polymer resin are converted into voids (121 in FIG. 2) in the subsequent coating film-forming step S3, and the voids (121 in FIG. 2) are used as light-scattering particles to improve optical characteristics of the optoelectronic device (100 in FIG. 2). Thus, in the bubble density-controlling step S2, the period for which the polymer resin is exposed to the vacuum may be controlled according to the intended density of the bubbles.

Finally, referring to FIG. 2, the coating film-forming step S3 is a step of forming the coating film 120 having the number of voids 121 dispersed therein by coating a substrate 110 with the polymer resin and then drying the polymer resin. In the coating film-forming step S3, the substrate 110 can be coated with the polymer resin using one coating method selected from among spin coating, bar coating, and spray coating. Here, when the film for optoelectronics manufactured according to the present embodiment is used in flexible OLEDs, a flexible substrate may be used as the substrate 110 in the coating film-forming step S3. In addition, in the coating film-forming step S3, when the film for optoelectronics manufactured according to the present embodiment is used for an internal light extraction layer of an OLED, it is possible to set the refractive index of the coating film 120 formed from a UV curable resin to be within a range of 1.3 to 1.7 by adjusting curing conditions.

When the coating film-forming step S3 is completed as described above, the film for optoelectronics including the substrate 110 and the coating film 120 coating the substrate 110, with the number of voids 121 being dispersed in the coating film 120, is manufactured. Here, the voids 121 dispersed within the coating film 120 are converted from the bubbles formed in the bubble-forming step S1, with the density of the bubbles being controlled in the bubble density-controlling step S2.

In addition, as illustrated in FIG. 2, the film for optoelectronics manufactured according to the present embodiment may be disposed on one surface of an organic-inorganic composite layer 130 that is a component of the optoelectronic device 100, such as an OLED or a photovoltaic cell, to improve optical characteristics of the optoelectronic device 100.

When the optoelectronic device 100 including the film for optoelectronics manufactured according to the present embodiment is a photovoltaic cell, the organic-inorganic composite layer 130 may include a transparent conductive oxide electrode, a light-absorbing layer, a rear electrode layer, and an insulating film. Examples of a material for the light-absorbing layer may include semiconductor compounds, such as monocrystalline or polycrystalline silicon, copper indium gallium selenide (CIGS) and cadmium telluride (CdTe); dye-sensitizers in which photosensitive dye molecules are adsorbed on the surface of nanoparticles of a porous film such that electrons are activated when the photosensitive dye molecules absorb visible light; amorphous silicon; etc.

When the optoelectronic device 100 in which the film for optoelectronics manufactured according to the present embodiment is used is an OLED, the organic-inorganic composite layer 130 may have a multilayer structure of an anode, an organic light-emitting layer, and a cathode. Here, the anode may be formed from a metal, such as gold (Au), indium (In), or tin (Sn), or a metal oxide, such as an indium tin oxide (ITO), that has a higher work function to facilitate hole injection. The cathode may be a metal thin film formed from Al, Al:Li or Mg:Ag that has a lower work function to facilitate electron injection. When the optoelectronic device 100 has a top emission structure, the cathode may have a multilayer structure including a semitransparent electrode thin film formed from a metal, such as Al, Al:Li, or Mg:Ag, and a transparent electrode thin film formed from an oxide, such as ITO, to facilitate the transmission of light generated by the organic light-emitting layer. The organic light-emitting layer may include a hole injection layer, a hole transport layer, an emissive layer, an electron transport layer, and an electron injection layer, sequentially stacked on the anode. Due to this structure, when a forward voltage is applied between the anode and the cathode, electrons from the cathode migrate to the emissive layer through the electron injection layer and the electron transport layer, and holes from the anode migrate to the emissive layer through the hole injection layer and the hole transport layer. The electrons and the holes that have migrated into the emissive layer recombine with each other, thereby generating excitons. When excitons transit from an excited state to a ground state, light is emitted. The brightness of emitted light is proportional to the amount of current that flows between the anode and the cathode.

When the OLED is a white OLED used in a lighting system, the light-emitting layer may have, for example, a multilayer structure including a high-molecular light-emitting layer that emits blue light and a low-molecular light-emitting layer that emits orange-red light, as well as a variety of other structures, to emit white light. In addition, the OLED may have a tandem structure. That is, a plurality of organic light-emitting layers may be provided to alternate with interconnecting layers.

The foregoing descriptions of specific exemplary embodiments of the present disclosure have been presented with respect to the drawings. They are not intended to be exhaustive or to limit the present disclosure to the precise forms disclosed herein, and many modifications and variations are obviously possible for a person having ordinary skill in the art in light of the above teachings.

It is intended therefore that the scope of the present disclosure not be limited to the foregoing embodiments, but be defined by the Claims appended hereto and their equivalents.

[Description of the Reference Numerals in the Drawings]

| | |
|---|---|
| 100: optoelectronic device | 110: substrate |
| 120: coating film | 121: voids |

130: organic-inorganic composite layer

1. A method of manufacturing a film, comprising:
forming a plurality of bubbles within a polymer resin by stirring the polymer resin, the polymer resin comprising an ultraviolet curable resin;
controlling a density of the bubbles formed within the polymer resin by exposing the polymer resin containing the bubbles therein to a vacuum; and
forming a coating film having a plurality of voids dispersed therein by coating a substrate with the polymer resin and then drying the polymer resin, to obtain a film for an optoelectronic device.

2. The method of claim 1, wherein stirring the polymer resin is performed for 10 minutes or longer.

3. The method of claim 1, wherein a viscosity of the polymer resin ranges from 100 cP to 100,000 cP.

4. The method of claim 1, wherein controlling the density of the bubbles comprising:
inserting a bath containing the polymer resin into a desiccator, and
creating the vacuum in the desiccator by operating a vacuum pump connected to the desiccator.

5. The method of claim 4, wherein a period of time for which the vacuum pump is operated is inversely proportional to the density of the bubbles.

6. The method of claim 1, wherein coating the substrate is performed using one coating method selected from the group consisting of spin coating, bar coating, and spray coating.

7. The method of claim 6, wherein the substrate comprises a flexible substrate.
